(19) United States
(12) Patent Application Publication
(10) Pub. No.: US 2003/0048122 A1
(43) Pub. Date: Mar. 13, 2003

(54) Universal programmable delay cell

(76) Inventor: Tauseef Kazi, San Diego, CA (US)

Correspondence Address: QUALCOMM Incorporated, Attn: Patent Department, 5775 Morehouse Drive, San Diego, CA, 92121-1714, US

(21) Appl. No.: 09/950,753

(22) Filed: Sep. 10, 2001

(51) Int. Cl. H03H 11/26

(52) U.S. Cl. 327/276

(57) ABSTRACT

An circuit and method for minimizing clock skew in an integrated circuit. The circuit is configured as a combination of delay elements and connection matrices that by connecting input and output pins in the connection matrix the circuit designer can select the required delay value. The connection matrices are defined in the circuit synthesis process as non routable areas therefore the programmable delay cells are programed after the circuit design is complete without requiring the circuit to be re routed. By inserting standard programmable delay cells in the clock tree the circuit designer can build in adjustable compensation for a wide range of clock skew.

### BACKGROUND OF THE INVENTION

1. Field of the Invention

The present invention relates generally to the art of microelectronic integrated circuits, and more specifically to a circuit and a method for equalizing clock skew in an integrated circuit.

2. Background Art

A large integrated circuit, such as an Application Specific Integrated Circuit (ASIC), generally includes a number of logic elements and sub-elements in a hierarchal arrangement. The circuitry is driven by clock pulses that are applied through an input clock and distributed via interconnect wiring to the various elements of the circuit.

In order for the circuit to function properly, the clock pulses must arrive at each clocked circuit element at the same time. However, the lengths of the wiring that conduct the clock pulses to the different blocks will generally be different. Since the length of time required for an electrical signal to propagate through a wire is proportional to the length of the wire, the clock pulses will arrive at the blocks at different times.

In addition, clock signal paths often include multiple levels of logic elements and buffering. Skew results if there are unequal numbers of elements in the signal paths or if there are variations in how long it takes a signal to pass through various elements. How long it takes a signal to pass through an element depends upon several factors, including the propagation delay characteristics of the particular element, the number of loads the element is driving, and the temperature of the element. Any variation of these factors between two signal paths will cause skew in the clock signals. Even if these factors are identical, there may be variations between individual elements of the same type.

There are several reasons for attempting to eliminate skew. First, it limits the speed at which a system can run. Within a computer, tasks are often performed serially, with data being passed from one stage of the computer to another on subsequent clock cycles. The time period of the clock must be long enough to account for the time it takes a stage to process the data and propagate it to the next stage.

Similarly, clock skew may prevent a system from being slowed down. It is often desirable to slow down a system clock for diagnostic purposes, but if slowed down too much, the system may no longer function.

The effectiveness and practicality of existing skew reduction methods varies. Equalizing wire lengths, balancing the numbers of elements, and element loading must be done during the initial design phase, and thus cannot account for design changes or component variations. Equalizing the number of elements in the path and the element loading may not be possible in all circumstances due to other design constraints of the circuit. Additionally, a previously equalized circuit may require the addition of new circuitry not conceived of during the initial design phase. Previously equalized paths may no longer be equalized after the addition of new circuitry.

It is clear that there exists a long and unfilled need for a technique capable of reducing clock skew while eliminating the shortcomings discussed above. The present invention solves these problems and provides circuit designers with a simple and inexpensive method for reducing integrated circuit clock skew.

### BRIEF SUMMARY OF THE INVENTION

The invention is a universal programmable delay cell and a method for its use. The programmable delay cell comprises delay elements and connection matrices. Each connection matrix has a plurality of inputs and an output, with the connection matrix output being coupled to the delay cell output. At least one delay element is coupled to the delay cell input and the delay elements are arranged to provide a desired delay value at the connection matrix input. The connection matrix output is selectively couplable to the connection matrix input to provide a desired delay at the delay cell output.

A preferred embodiment of the present invention is an integrated circuit comprising a reference signal input, a programmable delay cell and a logic element where the programmable delay cell is connected between the logic element and the reference signal.

The present invention includes a method of using the programmable delay in the design of an integrated circuit that comprises the steps of coding a design, synthesizing the code into hardware cells and determining the physical placement of the hardware cells. A clock tree is synthesized, programmable delay cells are inserted, the circuit wiring is routed, a clock tree analysis is performed, a delay value to balance the signal delays in the clock tree is selected and the delay cell is programmed with the desired delay. Programming of the delay cell is performed without affecting the previously routed circuit wiring.

The invention also includes a method for using the programmable delay cell in the design of a clock tree. This method comprises the steps of synthesizing a clock tree, inserting a programmable delay cell, performing clock tree analysis and reconfiguring the programmable delay cells to balance the clock tree delays.

An advantage of the universal programmable delay cell is a reduction in the amount and complexity of hardware necessary to correct clock skew.

Another advantage of the present invention is the ability to program the delay cell without affecting existing circuit wiring. This reduces the effort expended to balance clock skew during initial circuit design.

A further advantage of the programmable delay cell is its use as a tool in the designers toolkit that allows a complex problem like clock skew to be solved by a standardized design method for a variety of circuit types.

The foregoing and other features and advantages of the invention will be apparent from the following, more particular description of a preferred embodiment of the invention, as illustrated in the accompanying drawings.

### BRIEF DESCRIPTION OF THE DRAWINGS/FIGURES

In the figures, the left most digit of each reference number indicates the number of the figure in which the number is first referenced.

FIG. 1 illustrates the preferred embodiment of the universal programmable delay cell.

FIG. 2 illustrates use of the programmable delay cell in a clock tree.

FIG. 3 illustrates a simplified version of the universal programmable delay cell.

### DETAILED DESCRIPTION OF THE INVENTION

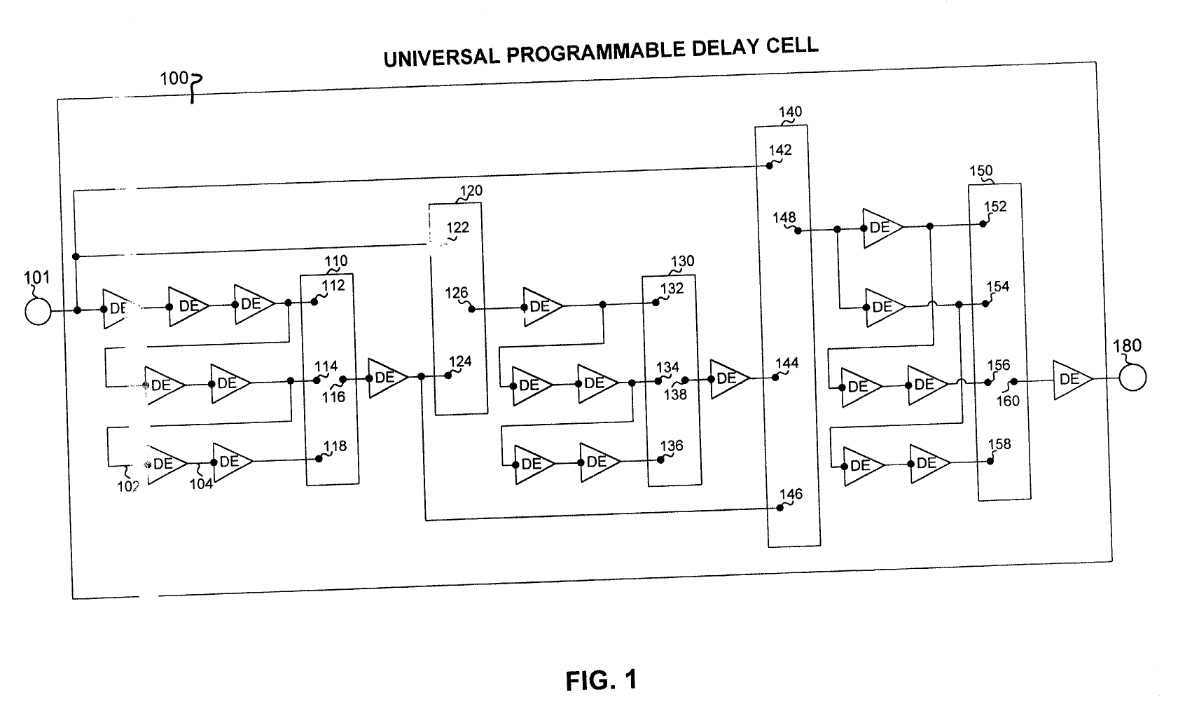

The present invention comprises a universal programmable delay cell and a method of using it in the design of integrated circuits. A preferred embodiment of a universal programmable delay cell 100 is illustrated in FIG. 1. The basic building blocks of the universal programmable delay cell, are delay elements DE and connection matrices 110, 120, 130, 140, 150. Each delay element DE has an element input 102 and an element output 104. Each delay element DE is selected to produce a time delay between the element input 102 and output 104. For ease of reference, only one set of delay element inputs and outputs is labeled. It should be understood that each delay element DE has a corresponding input and output. Suitable delay element DE devices include wire runs, diodes, transistors, resistors and other devices that a person skilled in the art would understand exhibit the desired delay characteristics.

Connection matrices 110, 120, 130, 140 and 150 have input pins (112, 114, 118, 122, 124, 132, 134, 136, 142, 144, 146, 152, 154, 156, 158) and output pins (116, 126, 138, 148, 160). The area bounding the input and output pins defines the footprint of the connection matrix; that is, pins 112, 114, 116, 118 for connection matrix 110; pins 122, 124, 126 for connection matrix 120; pins 132, 134, 136, 138 for connection matrix 130; pins 142, 144, 146, 148 for connection matrix 140 and pins 152, 154, 156, 158, 160 for connection matrix 150. The input and output pins of each matrix are placed as close together as possible to minimize the footprint of the connection matrix.

The footprints of connection matrices 110, 120, 130, 140, 150 are minimized in the circuit design process. This results in the circuit synthesis process placing no metal between the matrix input and output pins. By leaving the area between the matrix input and output pins free of metal, the connections necessary to program the delay cell can be accomplished without affecting existing circuit wire runs and so can be done after the necessary delay values have been determined. A person skilled in the art will understand the methods used to inhibit regions of an integrated circuit from being routed. In essence, if the distance between the matrix inputs and outputs is made sufficiently small, the computer program used to design the circuit configuration will route circuit wiring runs around, and not through, the connection matrices.

Universal programable delay cell 100 comprises a cell input 101 and a cell output 180. Cell input 101 is connected to connection matrix input pins 122, 142 and through three delay elements DE to connection matrix input pin 112. Connection matrix input pin 112 is connected through two delay elements DE to input pin 114. Connection matrix input pin 114 is connected through two delay elements DE to input pin 118. Connection matrix output pin 116 is connected through one delay element DE to connection matrix input pin 124. Connection matrix input pin 124 is connected to connection matrix input pin 146. Output pin 126 is connected through one delay element DE to input pin 132. Input pin 132 is connected through two delay elements DE to input pin 134. Input pin 134 is connected through two delay elements DE to input pin 136. Output pin 138 is connected through one delay element DE to input pin 144. Output pin 148 is connected through one delay element DE to input pin 152. Output pin 148 is connected through one delay element DE to input pin 154. Input pin 152 is connected through two delay elements DE to input pin 156. Input pin 154 is connected through two delay elements DE to input pin 158. Output pin 160 is connected through one delay element DE to cell output 180.

Programmable delay cell 100 is programmed by connecting the appropriate connection matrix input and output pins. For example if a delay value between cell input 101 and cell output 180 of 2 delay units (2 units of the amount povided by element DE) is desired then pins 142 and 148, 152 and 160 are connected. If 18 delay units is desired then pins 118 and 116, 124 and 126, 136 and 138, 144 and 148, 156 and 160 are connected. The preferred embodiment in FIG. 1 provides a range of 2-18 delay units, programmable by configuring the connection matrices.

In a further embodiment, delay elements DE with delay values that are a multiple of DE are used in the programmable delay cell 100. Using delay elements DE with larger delay values in the programmable delay cell 100 provides great flexibility in the range of delay available to the circuit designer. For example, if the delay elements DE in FIG. 1 are replaced with delay values of 4 times DE, the range of the delay programmable is 8 to 72 units. Varying the delay value of element DE provides great flexibility in selecting the possible range of delay values in the programmable delay cell 100.

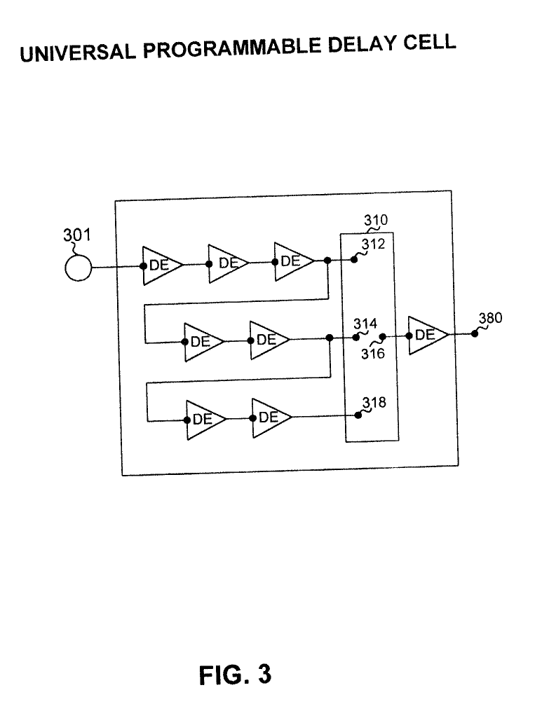

These embodiments present a sample of the many ways the delay elements and connection matrices could be connected to provide the desired range of programmable delay values. There can be more or less than the 5 connection matrices illustrated in FIG. 1. The embodiment in FIG. 1 could be simplified where a smaller range of delay values is needed. A simple example is shown in FIG. 3. This embodiment employs a single connection matrix 310. This would provide the programmable delay cell with the possible values, between cell input 301 and cell output 380, of 4 delay units if matrix input 312 is connected to matrix output 316 or 6 delay units if matrix input 314 is connected to matrix output 316 or 8 units if matrix input 318 is connected to matrix output 316. As in the preferred embodiment, the value of delay is determined by selectively connecting the input and output pins on the respective connection matrices. One of skill in the art would understand how to connect delay elements DE and connection matrices 110, 120, 130, 140, 150 in a programmable delay cell 100 to provide the desired range of selectable delay values

The circuit designer defines the high level functional specification for the desired circuit. The high level design is completed using abstract drawings, block diagrams, pseudo code and other methods well known in the art. The design is then coded into a circuit design language such as Very High Scale Integrated Circuit Hardware Description Language (VHDL) which synthesizes hardware from the design specification. The VHDL code is functionally verified to make sure the design conforms to the specification. The VHDL code is then turned into hardware components by an automated tool that uses standard hardware cells as building blocks. The VHDL design code is mapped into the standard hardware cells. The circuit designer places the programmable delay cells 100 (one of the standard hardware cells) in the root of every clock subtree. One important feature of the delay cell design is to minimize spacing between input and output pins of a given matrix. For example, input pins 112, 114 and 118 of matrix 110 should be placed very close to output pin 116. Similar considerations apply to matrices 120, 130, 140 and 150. This will inhibit the VHDL design software from laying a wire lead between the matrix inputs and outputs during the design phase.

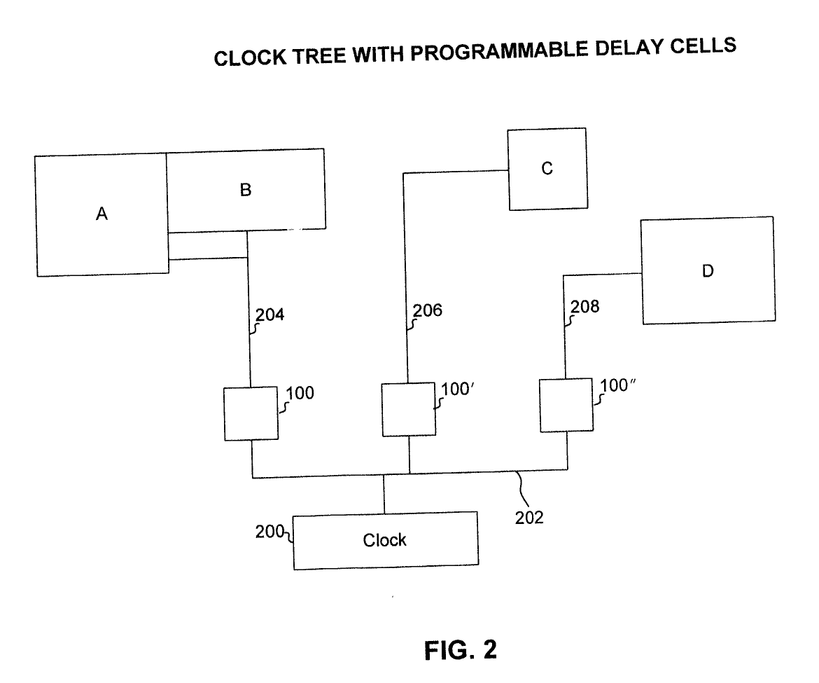

FIG. 2 illustrates the placement of the programable delay cell 100 into a clock tree. In the example shown a clock tree 202 comprises three clock subtrees 204, 206 and 208. A clock subtree is defined as a clock tree that is small enough to balance the routing delay to each logic element in that subtree. Clock subtree 204 includes a clock 200, programmable delay cell 100 and logic elements A and B. Clock subtree 206 includes clock 200, programmable delay cell 100′ and logic element C. Clock subtree 208 includes clock 200, programmable delay cell 100″ and logic element D. The number of clock subtrees used in a given circuit generally depends on the physical location of the several logic elements relative to each other that require timing synchronization. The programmable delay cells 100 are initially set to the minimum delay configuration. The chip is then routed and all wires are assigned physical location and layers. Clock tree analysis is performed to find the delays to each logic element. The programmable delay elements on the subtrees with smaller delays are then reconfigured to the delay values that will balance delays on the clock tree.

While the invention has been particularly shown and described with reference to several preferred embodiments thereof, it will be understood by those skilled in the art that various changes in form and detail may be made therein without departing from the spirit and scope of the invention as defined in the appended claims.

What is claimed:

1. A programmable delay cell, comprising:
a cell input;
a cell output;
a plurality of delay elements, each having an element input and an element output, at least one element input being coupled to said cell input; and
a connection matrix having a plurality of inputs and an output, said connection matrix output being coupled to said cell output;
said connection matrix inputs being coupled to one or more of said delay element outputs;
wherein said connection matrix inputs are selectively couplable to said connection matrix output to provide a desired delay at said cell output.

2. A programmable delay cell according to claim 1, further comprising:
a plurality of connection matrices;
a first plurality of delay elements coupled between said cell input and a first connection matrix; and
a second plurality of delay elements coupled between an output of said first connection matrix and a second connection matrix.

3. A programmable delay cell according to claim 1, wherein said connection matrix inputs are disposed closely adjacent said connection matrix output on a circuit layout to inhibit the placing of connection leads in the space between said connection matrix inputs and connection matrix output.

4. A method of designing a logic circuit incorporating a programmable delay cell, comprising the steps of:
(a) laying out logic elements of the logic circuit, wherein at least one logic element comprises a clock circuit;
(b) laying out the programmable delay cell, which comprises a cell input, a cell output, a plurality of delay elements, each having an element input and an element output, at least one element input being coupled to said cell input, a connection matrix having a plurality of inputs and an output, the connection matrix output being coupled to the cell output, the connection matrix inputs being coupled to one or more of the delay element outputs;
(c) routing connection leads from the clock circuit to the programmable delay cell input and from the programmable delay cell output to the remaining logic elements of the logic circuit;
(d) performing a clock tree analysis to determine the delays between the clock circuit and the remaining logic elements; and
(e) configuring the programmable delay cell to balance the delays among the logic elements of the logic circuit.

5. The method according to claim 4, comprising the further steps of:
(f) initially configuring the programmable delay cell to have a minimum delay effect;
(g) thereafter performing step (d); and
(h) thereafter reconfiguring the programmable delay cell to balance the delays among the logic elements.

6. The method according to claim 4, comprising the further step of:
(f) locating the connection matrix inputs closely adjacent the connection matrix output to thereby inhibit the placing of connection leads to remaining logic elements of the logic circuit between the connection matrix inputs and connection matrix output.

7. An integrated circuit, comprising:
a plurality of logic elements, wherein at least one logic element comprises a clock circuit;
a programmable delay cell, having
a cell input,
a cell output,
a plurality of delay elements, each having an element input and an element output, at least one element input being coupled to said cell input,
a connection matrix having a plurality of inputs and an output, the connection matrix output being coupled to the cell output,
the connection matrix inputs being coupled to one or more of the delay element outputs;
means for coupling the clock circuit to the programmable delay cell input; and
means for coupling the programmable delay cell output to at least one of the remaining logic elements;
wherein said connection matrix inputs are selectively couplable to said connection matrix output to provide a desired delay at said cell output.
